(19) United States
(12) Patent Application Publication
(10) Pub. No.: US 2025/0327180 A1
(43) Pub. Date: Oct. 23, 2025

(54) HIGH TEMPERATURE COATINGS FOR A PRECLEAN AND ETCH APPARATUS AND RELATED METHODS

(71) Applicant: ASM IP Holding B.V., Almere (NL)

(72) Inventors: Peipei Gao, Tempe, AZ (US); Xing Lin, Chandler, AZ (US); Alexandros Demos, Scottsdale, AZ (US); Chuang Wei, Chandler, AZ (US); Wentao Wang, Phoenix, AZ (US); Mingyang Ma, Phoenix, AZ (US); Prajwal Nagaraj, Tempe, AZ (US)

(21) Appl. No.: 19/257,828

(22) Filed: Jul. 2, 2025

Related U.S. Application Data
(63) Continuation of application No. 16/172,535, filed on Oct. 26, 2018, now Pat. No. 12,378,665.

(51) Int. Cl. C23C 16/455; C23C 16/02; H01J 37/32; H01L 21/67

(52) U.S. Cl. CPC C23C 16/45536; C23C 16/0245; C23C 16/45565; H01J 37/32357; H01J 37/32449; H01J 37/32495; H01L 21/67023; H01J 2237/3321; H01J 2237/3341

(57) ABSTRACT

A coating and a method to form the coating is proposed for a semiconductor film pre-clean and etch apparatus. The coating may be employed in environments where it is difficult to use a traditional coating or coating method. The coatings provide advantages including: an ability to effectively deliver hydrogen radicals and fluorine radicals to a wafer surface in one apparatus or individually in two apparatuses; a coverage of high aspect ratio features on critical components; an operability in high temperatures exceeding 150° C.; and a protection of a part with high aspect ratio features underneath the coating, thereby preventing metal and particles on a processed wafer.

This application is a divisional of, and claims priority to, U.S. patent application Ser. No. 16/172,535 filed Oct. 26, 2018 titled HIGH TEMPERATURE COATINGS FOR A PRECLEAN AND ETCH APPARATUS AND RELATED METHODS, the disclosure of which is hereby incorporated by reference in its entirety.

### FIELD OF INVENTION

The present disclosure generally relates to an apparatus for performing a pre-clean or an etch process on semiconductor wafers and related methods. More particularly, the disclosure relates to coatings for parts within the apparatus formed via an atomic layer deposition (ALD) process. The coatings provide advantages of being able to effectively deliver hydrogen radicals and fluorine radicals to a wafer surface in one apparatus or individually in two apparatuses formed by a remote plasma unit, cover high aspect ratio features on critical components and operate in a high temperature condition with metal-free and particle-free performance.

### BACKGROUND OF THE DISCLOSURE

Coatings have been employed on parts within semiconductor film manufacturing apparatuses in order to avoid particle generation that could adversely affect a film formed on a semiconductor wafer. These coatings have been found in particular on apparatuses where pre-clean or etch processes may take place. The coatings may include metals and ceramics, such as nickel, aluminum oxide, yttrium oxide, zirconium oxide, magnesium oxide, or calcium oxide, for example. The pre-clean or etch processes may involve a chemistry or a plasma that may react with the parts below the coatings. Thus, the coatings serve as a protective barrier for the parts.

However, there are some issues with these traditional coatings. First, hydrogen radicals show extremely fast recombination on some coatings such as nickel, which is commonly used as a protective barrier in fluorine radical environments. Carbon removal function cannot be achieved in this apparatus because of a limited amount of hydrogen radicals being delivered to a wafer.

Second, it is a big challenge for traditional coatings to accommodate both oxide removal and carbon removal using reactive F and H in one apparatus, respectively. Between one chemical process to the other, fluorine, hydrogen, and coating material may react and generate particles. Seasoning steps or dummy wafers may be needed to contain this problem, but it leads to low throughput.

Third, certain coatings may not be able to withstand environments where the temperature exceeds 150° C. Many pre-clean/etch processes may exceed the temperature of 150° C., so these coatings may prove to be detrimental in use at those higher temperatures due to physical and chemical decomposition of the coatings during the processes. For example, plasma spray Y₂O₃ coating cracks upon heating to around 150° C., leading to particle generation. Aluminum metal issues show up on wafer with anodized, PEO and ALD Al₂O₃ coatings in the reactive fluorine and reactive hydrogen chemical environment above 150° C.

Fourth, there may be difficulty in applying a coating uniformly on parts with high aspect ratio features. For example, a coating applied via a plasma spray process may not be able to cover high aspect holes on showerhead and gas distribution tunnels. The uncovered substrate may result in generation of particles that can adversely affect a film formed on a semiconductor wafer.

As a result, an ex-situ or in-situ coating that is able to efficiently deliver hydrogen radicals to wafers, while withstanding higher temperatures and harsh chemical environments is desired in apparatuses delivering both reactive fluorine and reactive hydrogen species. It is also desired that the coating be applied with a uniform thickness and not generate metal/particles when subjected to the higher temperatures and harsh chemical environments.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with at least one embodiment, a semiconductor film pre-clean/etch apparatus comprises: a reaction chamber; a wafer holder within the reaction chamber configured to hold a semiconductor wafer; a gas transport path configured to ensure a gas delivery to the reaction chamber and a uniform mixture of at least two gases; a gas distribution device for dispersing a gas across the semiconductor wafer; a gas manifold to help deliver hydrogen radical to wafer edge; a remote plasma unit that converts a first gas provided by a first gas source into a radical gas; wherein at least one of the wafer holder, the reaction chamber, the gas transport path, the gas distribution device, the gas manifold, or the remote plasma unit comprises a coating with a first layer and a second layer; wherein at least one of the first layer or the second layer of the coating is formed by atomic layer deposition (ALD); and wherein the first layer and the second layer comprise different materials.

In accordance with at least one embodiment, a method for forming a coating for a semiconductor film pre-clean/etch apparatus comprises: preparing a first surface to be coated; cleaning the first surface; depositing a first coating layer on the first surface with an atomic layer deposition (ALD) technique; depositing a second coating layer on the first coating layer to form a multi-layer coating; repeating the step of forming the first coating layer and forming the second coating layer as required; and performing a post-coating treatment on the composite coating; wherein the first coating layer comprises a material different from that of the second coating layer; wherein the semiconductor film deposition apparatus comprises: a wafer holder; a reaction chamber; a gas transport path, a gas distribution device; a gas manifold; and a remote plasma unit; and wherein the composite coating is disposed on at least one of: the wafer holder; the reaction chamber; the gas transport path, the gas distribution device; the gas manifold; or the remote plasma unit.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a cross-sectional illustration of a semiconductor film pre-clean apparatus with an ex-situ coating in accordance with at least one embodiment of the invention.

FIG. 2 is a cross-sectional illustration of a semiconductor film pre-clean apparatus with an in-situ coating in accordance with at least one embodiment of the invention.

FIGS. 3A and 3B are cross-sectional illustrations of an example of parts with enclosure space, a remote plasma unit, in accordance with at least one embodiment of the invention.

FIGS. 4A and 4B are cross-sectional illustrations of parts with high aspect ratio features, a gas distribution system or showerhead, in accordance with at least one embodiment of the invention.

FIG. 5 is a cross-sectional illustration of a part with a coating arrangement in accordance with at least one embodiment of the invention.

FIG. 6 is a cross-sectional illustration of a part with a coating arrangement in accordance with at least one embodiment of the invention.

FIG. 7 is a cross-sectional illustration of a part with a coating arrangement in accordance with at least one embodiment of the invention.

FIG. 8 is a flowchart illustrating a method of coating in accordance with at least one embodiment of the invention.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

As used herein, the term “atomic layer deposition” (ALD) may refer to a vapor deposition process in which deposition cycles, preferably a plurality of consecutive deposition cycles, are conducted in a process chamber. Typically, during each cycle, the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition,” “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which may react and/or decompose on a substrate surface to produce a desired deposition.

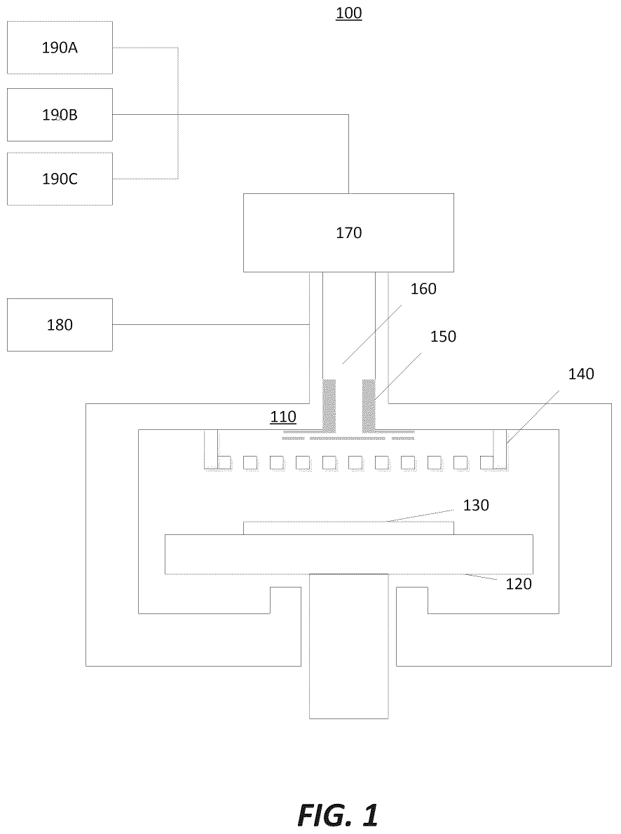

FIG. 1 illustrates a semiconductor film pre-clean apparatus 100 with an ex-situ coating in accordance with at least one embodiment of the invention. The semiconductor film pre-clean apparatus 100 comprises: a reaction chamber housing 110; a wafer holder or susceptor 120, configured to hold a semiconductor wafer 130; a gas distribution system or showerhead 140; a gas manifold 150; a gas transport path 160; a remote plasma unit 170; a first gas source 180; a second gas source 190A; a third gas source 190B; and a fourth gas source 190C.

The remote plasma unit 170 converts a gas provided by the first gas source 180 into a radical gas. An example of a radical gas may include a fluorine radical gas used to remove a film, such as silicon oxide (SiOₓ) or silicon germanium oxide (SiGeOₓ), from the semiconductor wafer 130. The second gas source 190A may provide a dilute gas or a reactant gas with the gas from the first gas source 180 to the semiconductor wafer 130 in order to remove a film, such as silicon oxide or silicon germanium oxide. The third gas source 190B may provide a gas activated by remote plasma unit 170 to form a hydrogen radical gas during carbon removal process. The fourth gas source 190C may provide an inert gas to help ignite remote plasma unit 170 and may also deliver radicals to wafer 130. The gas transport path 160 ensures a uniform mixture of gas from the first gas source 180 and the second gas source 190A to be delivered to the reaction chamber 110. The gas distribution system or showerhead 140 distributes the gases evenly over the surface of the semiconductor wafer 130. The gas manifold 150 may assist in efficiently delivering a radical gas generated from the third gas source 190B to wafer edge and improving carbon removal uniformity.

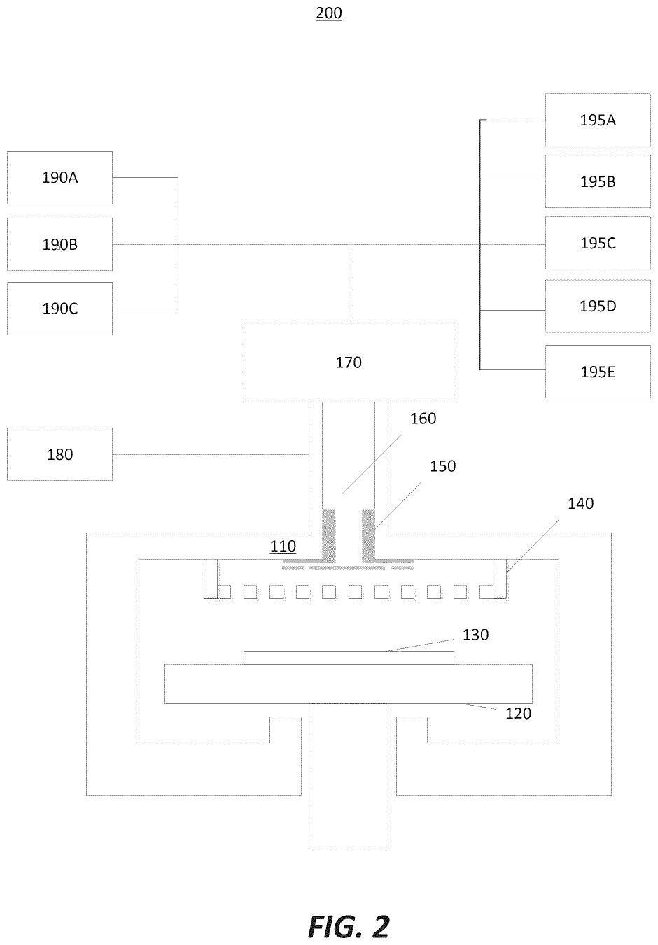

FIG. 2 illustrates a semiconductor film pre-clean apparatus 200 with an in-situ coating in accordance with embodiments of the invention. The semiconductor film pre-clean apparatus 200 comprises: a reaction chamber housing 110; a wafer holder or susceptor 120, configured to hold a semiconductor wafer 130; a gas distribution system or showerhead 140; a gas manifold 150; a gas transport path 160; a remote plasma unit 170; a first gas source 180; a second gas source 190A; a third gas source 190B; a fourth gas source 190C; a plurality of precursor sources 195A-195D; and a fifth gas source 195E.

Similar to the ex-situ coating apparatus 100, the in-situ coating apparatus 200 may also add precursor and purge gas sources to allow for an in-situ coating function. Taking the example of composite coating or dual-layer-coating with ALD-deposited alumina (Al₂O₃) and ALD-deposited yttrium oxide (Y₂O₃), the in-situ coating apparatus 200 may include a trimethylaluminum (TMA) source 195A and a water (H₂O) source 195B for in-situ ALD-deposited alumina coating. The in-situ coating apparatus 200 may include an yttrium gas source 195C (such as Y(thd), CP₃Y, or (CpCH₃)₃Y, for example) and an oxygen gas source 195D (such as oxygen, ozone, a mixture of ozone and oxygen, or H₂O, for example) for in-situ ALD-deposited yttrium oxide (as described in U.S. Pat. No. 7,351,658, which is herein incorporated by reference). Moreover, a purge gas source 195E may be connected from an upper stream of precursor gas sources (195A-195D) to remove excess precursors or precursor by-products after conversion of a chemisorbed precursor.

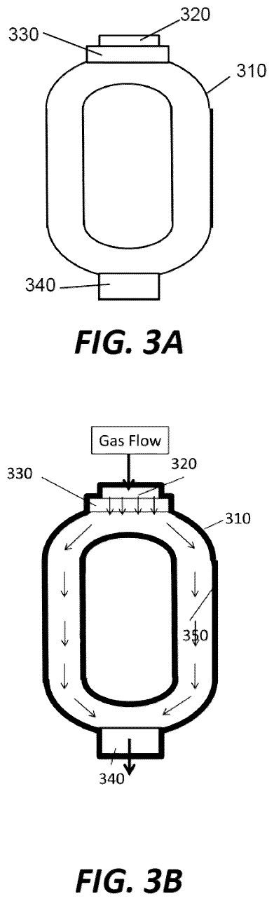

Several types of part structures can be beneficial from the coating method. One type of structures is parts with enclosure space, such as a remote plasma unit, where the radical gas is initially generated. Remote plasma units may require a coating, because of the plasma bombardment and corrosive chemical environment. However, common coating methods either show problems or are not feasible. For example, particles generated on common RPU coatings, such as anodize and PEO, can transit between carbon removal and oxide removal processes. Plasma spray cannot coat due to the enclosed space and a small gas inlet/outlet. FIGS. 3A and 3B illustrates a representative remote plasma unit 300. The remote plasma unit 300 comprises a main body 310, a gas inlet 320, an RF generator 330, a gas outlet 340, and a coating 350. The coating 350 covers the internal walls of the main body 310. Other portions of the remote plasma unit 300 may be covered by the coating 350. The coating 350 may comprise ceramic coatings, such as aluminum oxide (Al₂O₃), yttrium oxide (Y₂O₃), yttrium fluoride (YF₃), yttrium oxyfluoride (YOₓF_{y}), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), cerium oxide (CeO₂), or any combination of the above.

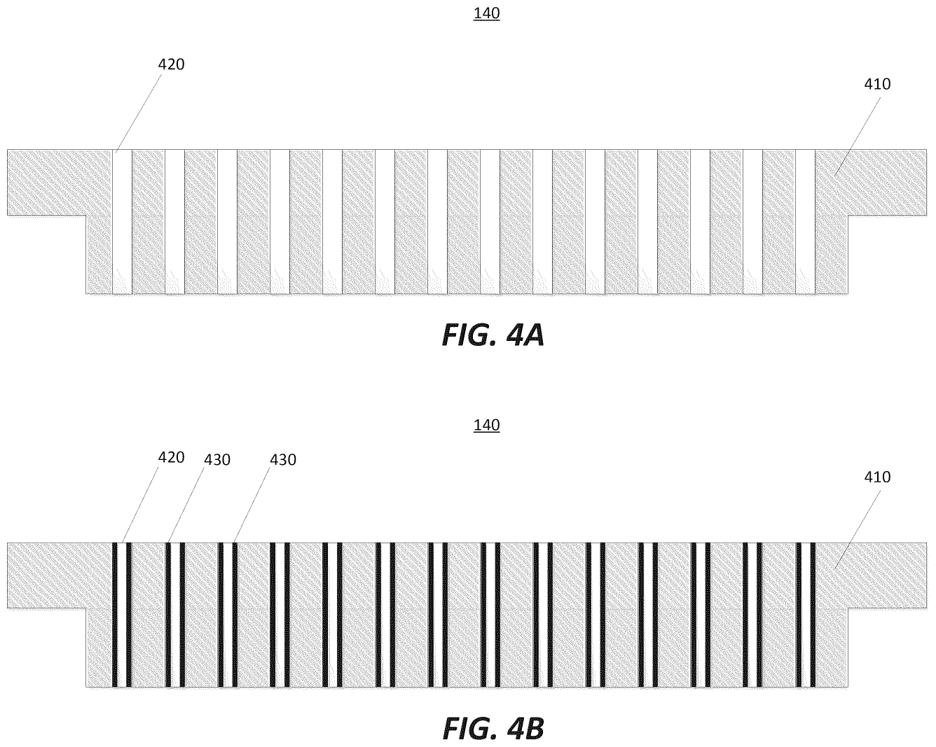

The gas distribution system or showerhead 140, gas delivery path 135, and gas manifold 150 are parts that may also be coated, as such parts are exposed to the radical gas generated by the remote plasma unit 170. FIG. 4A illustrates another type of parts with high aspect ratio holes such as the gas distribution system or showerhead 140 in accordance with at least one embodiment of the invention. The gas distribution system or showerhead 140 comprises a showerhead body 410 and a plurality of holes 420. Gas flows through the plurality of holes 420 onto the semiconductor wafer 130. The plurality of holes 420 may comprise features with high aspect ratios and may also comprise different shapes, such as bevels and curves. The features may provide large area surfaces on which particles can be generated from the bulk of the showerhead body 410.

FIG. 4B illustrates the gas distribution system or showerhead 140 that incorporates a coating to prevent the formation of particles. A plurality of coatings 430 are applied to the plurality of holes 420. The plurality of coatings 430 may comprise ceramic coatings, such as aluminum oxide (Al₂O₃), yttrium oxide (Y₂O₃), yttrium oxyfluoride (YOₓF_{y}), yttrium fluoride (YF₃), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), cerium oxide (CeO₂), or any combination of the above. The plurality of coatings 430 may also cover other portions of the showerhead body 410. While FIGS. 4A and 4B illustrate one geometry for coatings of the parts, there may be more complex internal structures to which the coatings may also apply. This may include the gas transport path 135 and the gas manifold 150, which may have holes and bends within the geometry.

The coatings of the parts may preferably be composite coatings. FIG. 5 illustrates one coating arrangement 500. The coating arrangement 500 includes a part 510 that is to be coated. The part 510 may be made of a material comprising at least one of: aluminum alloys, cast iron, stainless steel, Hastelloy, Inconel, nickel alloy, ceramics, ceramic coatings, or metal coatings. The part 510 is coated with a layer of a first coating 520, followed by a layer of a second coating 530, and repeated with a layer of the first coating 520 and a layer of the second coating 530. At least one or both of the first coating 520 or the second coating 530 may be applied via atomic layer deposition (ALD) techniques. The benefit of using an ALD technique includes the formation of a fully dense coat, while generating an isotropic microstructure. In cases where only one coating is done by ALD, the other coating may be done by anodization, chemical vapor deposition (CVD), plasma vapor deposition (PVD), plasma spray coating, or plasma electrolytic oxidation (PEO). The repeating of the layers may be done as desired or needed.

The first coating 520 may comprise one of: aluminum oxide (Al₂O₃), yttrium oxide (Y₂O₃), yttrium fluoride (YF₃), yttrium oxyfluoride (YOₓF_{y}), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), or cerium oxide (CeO₂). The second coating 530 may comprise one of: aluminum oxide (Al₂O₃), yttrium oxide (Y₂O₃), yttrium fluoride (YF₃), yttrium oxyfluoride (YOₓF_{y}), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), or cerium oxide (CeO₂). The first coating 520 and the second coating 530 ideally do not comprise the same materials.

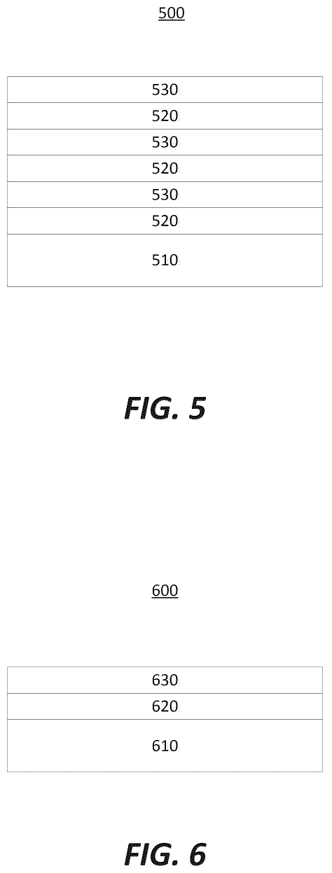

FIG. 6 illustrates a coating arrangement 600 in accordance with at least one embodiment of the invention. The coating arrangement 600 includes a part 610 that is to be coated. The part 610 may be made of a material comprising at least one of: aluminum alloys, cast iron, stainless steel, Hastelloy, Inconel, nickel alloy, ceramics, ceramic coatings, or metal coatings. The part 610 is coated with a layer of a first coating 620, followed by a layer of a second coating 630. At least one or both of the first coating 620 or the second coating 630 may be applied via atomic layer deposition (ALD) techniques. In cases where only one coating is done by ALD, the other coating may be done by anodization, chemical vapor deposition (CVD), plasma vapor deposition (PVD), plasma spray coating, or plasma electrolytic oxidation (PEO). The coating can be extended to more than two layers of different ALD coatings (such as yttrium oxide and aluminum oxide, for example) or may comprise only one layer of coating (such as yttrium oxide for example). The repetition of the layers may be done as desired or needed.

The first coating 620 may comprise one of: aluminum oxide (Al₂O₃), yttrium oxide (Y₂O₃), yttrium fluoride (YF₃), yttrium oxyfluoride (YOₓF_{y}), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), or cerium oxide (CeO₂). The second coating 630 may comprise one of: aluminum oxide (Al₂O₃), yttrium oxide (Y₂O₃), yttrium oxyfluoride (YOₓF_{y}), yttrium fluoride (YF₃), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), or cerium oxide (CeO₂). The first coating 620 and the second coating 630 ideally do not comprise the same materials.

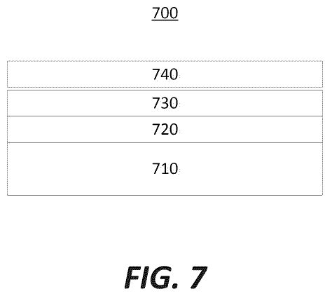

FIG. 7 illustrates a coating arrangement 700 in accordance with at least one embodiment of the invention. The coating arrangement 700 includes a part 710 that is to be coated. The part 710 may be made of a material comprising at least one of: aluminum alloys, cast iron, stainless steel, Hastelloy, Inconel, nickel alloy, ceramics, ceramic coatings, or metal coatings. The part 710 is coated with a layer of a first coating 720, followed by a layer of a second coating 730 and a layer of a third coating 740. At least one or all of the first coating 720, the second coating 730, and the third coating 740 may be applied via atomic layer deposition (ALD) techniques. In cases where only one coating is done by ALD, the other coating may be done by anodization, chemical vapor deposition (CVD), plasma vapor deposition (PVD), plasma spray coating, or plasma electrolytic oxidation (PEO). The coating can be extended to more than two layers of different ALD coatings or may comprise only one layer of coating. The repetition of the layers may be done as needed.

The first coating 720 may comprise one of: aluminum oxide (Al₂O₃), yttrium oxide (Y₂O₃), yttrium fluoride (YF₃), yttrium oxyfluoride (YOₓF_{y}), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), or cerium oxide (CeO₂). The second coating 730 may comprise one of: aluminum oxide (Al₂O₃), yttrium oxide (Y₂O₃), yttrium oxyfluoride (YOₓF_{y}), yttrium fluoride (YF₃), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), or cerium oxide (CeO₂). The third coating 740 may comprise one of: aluminum oxide (Al₂O₃), yttrium oxide (Y₂O₃), yttrium oxyfluoride (YOₓF_{y}), yttrium fluoride (YF₃), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), or cerium oxide (CeO₂). The first coating 720, the second coating 730, and the third coating 740 ideally do not comprise the same materials, such as yttrium oxide, hafnium oxide, and aluminum oxide.

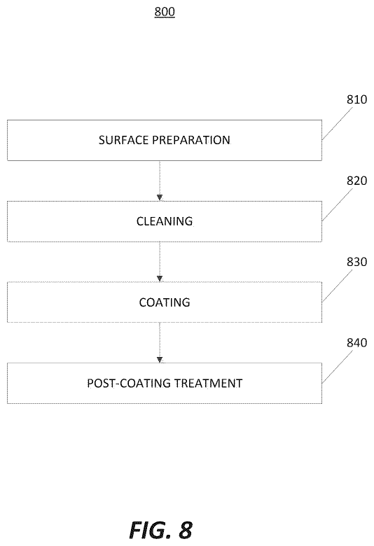

Coating of the parts may require several steps. FIG. 8 illustrates a method 800 for performing the coating. The method 800 comprises: a surface preparation step 810; a cleaning step 820; a coating step 830; and a post-coating treatment step 840. The substrate preparation step 810 may include steps to ensure an optimized coating, including removing sharp edges that could cause stress on the coating, tightening tolerances on gaps, and optimizing small hole design in order to reduce localized non-uniform coating defects or Newton's rings caused by trapped precursors during ALD coating. To increase coating adhesion and ensure good coating quality, parts may be treated by texturing, polishing, and/or electropolishing.

The cleaning step 820 may depend on the part being coated. The cleaning step 820 may remove surface carbon, particles, and excess metal from the part. The cleaning step 820 may include alkaline, acid, electro-cleaning, and/or ozone treatment steps among others. By performing the cleaning step 820, uniformity and surface coverage of the coating may be optimized.

The coating step 830 may comprise forming at least one coating layer by an ALD technique. The ALD technique may be done by in-situ or ex-situ methods. An exemplary method may be to form a first layer of aluminum oxide and a second layer of yttrium oxide via an ALD process (as described in U.S. Pat. No. 7,351,658, which is herein incorporated by reference). The thickness of the aluminum oxide on a gas distribution device or showerhead may range between: 1-10,000 nm; 10-2,500 nm; or 100-500 nm. If yttrium oxide is deposited as a coating for a gas distribution device or showerhead, the thickness of yttrium oxide may range between: 1-10,000 nm; 10-2,500 nm; or 100-500 nm. The thickness of the aluminum oxide on a remote plasma unit may range between: 1-50,000 nm; 10-25,000 nm; or 100-10,000 nm. If yttrium oxide is deposited on a remote plasma unit, the thickness of yttrium oxide may range between: 1-50,000 nm; 10-25,000 nm; or 100-10,000 nm.

A coating formed in the manner described above may be used reliably for processes running at temperatures above 150° C. In addition, the aluminum oxide layer may achieve better interfacial coating quality on the part to be coated in comparison to the yttrium oxide. The aluminum oxide layer then may reduce the stress in the yttrium oxide layer from thermal expansion, thereby reducing the potential for cracking in the yttrium oxide. The aluminum oxide layer may also be efficient at impeding migration of metals to the surface, such as magnesium and sodium.

The post-coating treatment step 840 may comprise improving the quality or properties of the coating. Examples may include fluorinating or chlorinating the surface of the coating to better accommodate environments that have fluorine or chlorine. In addition, the post-coating treatment step 840 may involve annealing the surface to remove internal stress and defects. Furthermore, by heating up to a certain temperature, binary or ternary ceramics can be achieved. For example, a composite coating of Al₂O₃ and Y₂O₃ can transform to yttrium aluminum garnet (YAG) or yttrium aluminum monoclinic (YAM) after high temperature treatment with a specific ratio of Al₂O₃ and Y₂O₃.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for forming a coating for a semiconductor apparatus comprising:
providing the semiconductor apparatus, wherein the semiconductor apparatus comprises a wafer holder, a reaction chamber, a gas transport path, a gas distribution device, a gas manifold, and a remote plasma unit;
preparing a first surface to be coated;
cleaning the first surface;
depositing a first coating layer on the first surface with an atomic layer deposition (ALD) technique;
depositing a second coating layer on the first coating layer to form a multi-layer coating; and
performing a post-coating treatment on the multi-layer coating;
wherein the first coating layer comprises a material different from that of the second coating layer, and
wherein the multi-layer coating is disposed on at least one of the wafer holder, the reaction chamber; the gas transport path, the gas distribution device, the gas manifold, and the remote plasma unit.

2. The method of claim 1, further comprising repeating the step of forming the first coating layer and forming the second coating layer.

3. The method of claim 1, wherein depositing the first coating layer is performed within the apparatus.

4. The method of claim 1, wherein depositing the second coating layer is performed by at least one of: anodization, chemical vapor deposition (CVD), plasma vapor deposition (PVD), plasma spray coating, or plasma electrolytic oxidation (PEO).

5. The method of claim 1, wherein the first coating layer comprises at least one of: aluminum oxide (Al₂O₃), yttrium oxide (Y₂O₃), yttrium fluoride (YF₃), yttrium oxyfluoride (YOₓF_{y}), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), or cerium oxide (CeO₂).

6. The method of claim 1, wherein the second coating layer comprises at least one of: aluminum oxide (Al₂O₃), yttrium oxide (Y₂O₃), yttrium fluoride (YF₃), yttrium oxyfluoride (YOₓF_{y}), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), or cerium oxide (CeO₂).

7. The method of claim 1, wherein the first coating layer is on the gas distribution device and a thickness of the first coating layer ranges between 1-10,000 nm.

8. The method of claim 1, wherein the second coating layer is on the gas distribution device and a thickness of the second coating layer ranges between 1-10,000 nm.

9. The method of claim 1, wherein the first coating layer is on the remote plasma unit and a thickness of the first coating layer ranges between 1-50,000 nm.

10. The method of claim 1, wherein the second coating layer is on the remote plasma unit and a thickness of the second coating layer ranges between 1-50,000 nm.

11. A method for forming a coating for an apparatus, the method comprising:
providing the apparatus, wherein the apparatus comprises:
a reaction chamber,
a wafer holder within the reaction chamber,
a gas transport path configured to ensure a gas delivery to the reaction chamber,
a gas distribution device configured to dispersing a gas,
a gas manifold,
a plurality of gas sources, and
a remote plasma unit;
forming at least one coating layer on at least one of the wafer holder, the reaction chamber, the gas transport path, the gas distribution device, the gas manifold, or the remote plasma unit,
wherein the at least one coating layer comprises one or more of aluminum oxide (Al₂O₃), yttrium oxide (Y₂O₃), yttrium fluoride (YF₃), yttrium oxyfluoride (YOₓF_{y}), aluminum fluoride (AlF₃), scandium oxide (Sc₂O₃), hafnium oxide (HfO₂), lanthanum oxide (La₂O₃), samarium oxide (Sm₂O₃), gadolinium oxide (Gd₂O₃), erbium oxide (Er₂O₃), zirconium oxide (ZrO₂), or cerium oxide (CeO₂).

12. The method of claim 11, wherein the at least one coating layer is formed by an atomic layer deposition (ALD) process.

13. The method of claim 11, wherein forming the at least one coating layer is performed in situ.

14. The method of claim 11, wherein forming the at least one coating layer comprises forming a first coating layer and a second coating layer disposed on the first coating layer, wherein the first coating layer comprises aluminum oxide and the second coating layer comprises yttrium oxide.

15. The method of claim 11, wherein the at least one coating layer has a thickness of 1-50,000 nm.

16. The method of claim 11, wherein the plurality of gas sources comprise an yttrium source and an oxygen source.

17. The method of claim 11, wherein the at least one coating layer is formed on an internal wall of the remote plasma unit.

18. The method of claim 16, wherein the yttrium source is a source of a gas selected from the group consisting of Y(thd)₃, Cp₃Y, and (CpCH₃)₃Y.

19. The method of claim 16, wherein the plurality of gas sources comprises an aluminum source.

20. The method of claim 19, wherein the wherein the aluminum source is a source of trimethylaluminum.
